(19) United States
(12) Patent Application Publication
(10) Pub. No.: US 2007/0090974 A1
(43) Pub. Date: Apr. 26, 2007

(54) PROCESS AND MEDIUM FOR RECORDING HIGH-DENSITY DIGITAL DATA

(76) Inventor: Jean-Fabien Dupont, Chalon-sur-Saone (FR)

Correspondence Address: David A. Novais;Patent Legal Staff, Eastman Kodak Company, 343 State Street, Rochester, NY, 14650-2201, US

(21) Appl. No.: 11/552,161

(22) Filed: Oct. 24, 2006

(30) Foreign Application Priority Data
Oct. 26, 2005 (FR) 0510913

(51) Int. Cl. H03M 7/00

(52) U.S. Cl. 341/50

(57) ABSTRACT

The invention is to provide a recording process that enables the density of recorded information to be increased on a two-dimensional medium comprising a printing surface, for example a strip of light sensitive film. The process is for a recording system for digital data (1) and a recording medium (7) to record the encoded data, for example a strip of photographic film. The process is used in particular to code data to be recorded at high density, for example the digital data of still or moving images, text, or sound.

### CROSS REFERENCE TO RELATED APPLICATION

This is an application claiming priority of French Patent Application No. 0510913, filed Oct. 26, 2005.

### FIELD OF THE INVENTION

The invention is in the technical field of coding and recording at high density of digital data on a medium comprising a recording surface. A “high-density” recording contains a high number of information per unit of measurement of the recording surface. The data to be recorded are for example the data of still or moving images (e.g. a video clip), of text or sound. The recording can be made by printing, for example on a photosensitive strip, such as a strip of photographic paper or film.

### BACKGROUND OF THE INVENTION

According to the usual terminology of the technical field, digital data constituting information are represented by a series of symbols. Each symbol belongs to a limited set. For example, an integer (information) is usually coded as a series of decimal figures (symbols) that can have ten different values. Each of these ten values is linked to a particular representation that is easy to distinguish from the others like: 0, 1, 2, 3, 4, 5, 6, 7, 8, 9 (symbolic representation with figures) or zero, one, two, three, four, five, six, seven, eight, nine (symbolic representation with letters).

The same series of digital data can be represented by series of different symbols. To return to the previous example, an integer can also be coded by means of binary figures, capable of taking two different values, represented, for example, by 0 and 1. It is always possible to go from one representation to the other. This operation, sometimes called transcoding, can modify the number of symbols required to code the information. Transcoding consists in translating information coded with one set (series) of symbols into equivalent information coded with another series of symbols. So, the number twenty one is represented by two decimal figures (21) and by five binary figures
(10101=1.2⁰+0.2¹+1.2²+0.2³+1.2⁴).

Recording, followed by the reading of information, is a process similar to the transmission of information between a transmitter and a receiver. In the case of transmission, the information varies according to the time axis, while for recording, the information varies according to one or several dimensions of the physical medium. From a practical point of view, the separation in time between the transmission operation (recording) and the reception operation (reading) makes the achievement of a return path between a receiver and a transmitter impracticable. Any management of the communication channel based on dialogue between the transmitter and the receiver is thus impossible.

In particular, in case of reception error, it is impossible, as is usually practiced in telecommunications, to request a retransmission of the erroneous part. Also, it is impossible to dynamically adapt the information flow rate to the quality variations of the transmission channel.

In the rest of the description, the expression “transmission channel” is used to indicate either a transmission system or a digital data storage system. In general the transmission system or digital data storage system will be called “recording system”.

A transmission channel uses a physical quantity that is specific to it to transmit the digital data. The physical quantity is, for example, the intensity of an electric current or magnetic field. This physical quantity, usually called signal, enables the representation of a series of symbols specific to the transmission channel. One function of the transmitter is to transcode the digital data to be transmitted into its set (series) of symbols and generate the physical quantity representative of these symbols.

In conjunction with this, one function of the receiver is to measure and analyze the transmitted physical quantity to deduct the value of the symbols. In the rest of the description, the physical quantity used by the transmission channel will also be called signal.

An information transmission channel has two basic characteristics that determine its capacity to transmit information: its bandwidth and its noise. These two characteristics can evolve during the use of the channel according to statistical laws.

The bandwidth is the area between the minimum frequency and the maximal frequency of the transmission channel. In other words, the bandwidth is the frequency range in which a transmission channel enables a signal to be conveyed without great distortion. The bandwidth sets a limit to the flow rate of symbols that the channel can transmit.

A transmission channel can use one or several carrier frequencies positioned in its bandwidth and modulated by the signal to be transmitted. The modulation of a carrier consists in modifying one or several of its characteristics, like its amplitude, phase or frequency according to the signal.

Noise is an unwanted interference which is superimposed on the signal. Consequently, noise reduces the receiver's capacity to distinguish the different values that the symbols can take and thus the quantity of information per symbol.

In practice, the signal is always altered by the transmission channel of a recording system. Consequently, the conversion between the received signal and the symbols coding the digital data is performed with a non-zero probability of error.

It is possible to add digital data additional to the digital data to be transmitted. These additional digital data enable errors introduced by the transmission channel to be detected, and advantageously corrected. The additional data are calculated from the initial digital data to be transmitted; they are thus redundant because they do not contain additional information.

There is a multitude of error detection or correction algorithms, like for example the checksum or the Reed-Solomon algorithms. In general, the greater the redundancy introduced by the algorithm, the better the error detection or correction capacity, but this occurs at the expense of the useful capacity of the transmission channel. There is thus an optimum to be found according to the characteristics of the transmission channel (bandwidth and noise).

The combination of a set of symbols to represent the digital data with an error detection or correction algorithm defines a coding algorithm. This coding algorithm gives the transmission channel a transmission capacity and an error probability depending on the characteristics of said channel.

Claude Shannon, in 1948, indicated the theoretical maximum capacity of information of a channel according to its noise and bandwidth characteristics, but without indicating any process to approach this limit.

Many systems of storing information in digital form have been developed. Mostly they can be considered as one-dimensional: the physical quantity (signal) used to represent the symbols varies in a single direction. When a surface is used to store digitized information, it is divided into tracks arranged to make their mutual interference insignificant. This is the case, for example, on optical disks (a spiral track), magnetic disks (several concentric tracks) or video tapes (helicoid tracks). In other words, the symbols representing the information are organized in a linear way on the surface and their line density is a basic characteristic of the system.

Nevertheless, some storage systems have a spatial density more or less equal in the two main directions of the recording surface and can be thus considered as two-dimensional.

U.S. Pat. No. 4,659,198 describes means to code information on a photographic film with spots. A practical application is the AatonCode used in cameras of the AATON® make. In this application, the block size is at least 0.2 mm a side, which gives a recording spatial density of about 20 bits/mm².

U.S. Pat. No. 5,544,140 refers to the use of photographic film to record sound signals in digital form using blocks having two different densities. One practical application is the Dolby® Digital system for the cinema. Blocks measuring 32 microns a side, which gives a recording spatial density of about 1000 bits/mm².

Following the two examples of the abovementioned patents, most digital recording systems only use two nominal values of the physical quantity to represent the symbols. Systems that use a magnetic medium only use the two opposite directions North and South, without taking intensity into account. Optical discs, as well as most barcodes, only use two levels of reflection of the incident light. The symbols thus contain only a single bit of information.

As described previously, the transmission channel's capacity can be increased by using symbols having more than two values and thus containing more information. The physical quantity (signal) then has more than two nominal values.

U.S. Pat. No. 5,369,261 describes means to code digital data on a surface using areas of different colors and intensities. The system described in U.S. Pat. No. 5,369,261 is known under the name of HueCode™. Although the patent describes very high spatial densities of information (more than 10⁶ bits/mm²), practical embodiments do not exceed 500 bits/mm², given limitations due to printing, the recording medium and the reader.

The disadvantage of state of the art process is that the decrease of block size entails interference between adjacent blocks having the effect of breaking the bijective relation between the symbol values and the optical density of the blocks. It is then no longer possible to retrieve the symbol value and thus retrieve the digital data from the optical density value of the blocks. This critical effect occurs as soon as the top limit of the bandwidth of the transmission channel is reached. In a two-dimensional recording system, using a recording surface, this effect is cumulative on both axes, severely limiting the spatial density effectively achieved by two-dimensional recording systems.

Consequently, it becomes necessary to adapt the recording process to increase the density of recorded information in a two-dimensional recording system.

### SUMMARY OF THE INVENTION

It is an object of the invention to solve the abovementioned state of the art problems, with a recording process adapted to solve the abovementioned problems of two-dimensional recording systems.

As described above, the frequency response of a transmission channel is more or less constant in the bandwidth, which enables the signal to be transmitted without great distortion. In the case of a recording surface, the frequency response does not become zero suddenly outside the bandwidth but decreases gradually. It is thus possible to transmit a higher frequency signal provided some signal distortion is admitted.

It is an object of the invention to provide a recording process of a series of digital data that enables the density of information recorded on a two-dimensional medium to be increased. The two-dimensional medium is, for example, a strip of light sensitive film. The invention process operates by splitting the transmission channel into several parts having different characteristics according to the frequency response of each part, and by using a coding algorithm suited to each part.

Implementation of the invention process requires the determination of a coding technique. The invention process, intended to record a series of digital data with a system having a two-dimensional spatial band, comprises the following steps:

a) selection in the band of spatial frequencies of disjoint subsets Eᵢ of carrier frequencies fₓ, f_{y};

b) linking with each subset Eᵢ of a coding algorithm Aᵢ function of a signal to noise ratio (S/N) of the system in the subset Eᵢ of carrier frequencies fₓ, f_{y}, so as to give to the subset Eᵢ a transmission capacity function of the coding algorithm Aᵢ and the number of carrier frequencies of the subset Eᵢ;

c) distribution of the data to be recorded in the subsets Eᵢ according to their transmission capacity;

d) coding of the data of every subset Eᵢ according to the coding algorithm Aᵢ linked to the subset Eᵢ by amplitude and phase modulation of the carrier frequencies;

e) generation of an image representing the sum of the modulated carrier frequencies; and

f) recording of the image with the recording system.

In a preferred embodiment of the invention, an addition of error correction codes is performed in the coding algorithm Aᵢ.

The system of the invention comprises a coding unit, a recording unit, a recording medium, a reading unit and a decoding unit, all these units being capable of intercommunicating digital data. The recording medium comprises a printing surface.

According to one advantageous embodiment of the invention, the image has the form of a rectangular pattern and each rectangular pattern comprises a plurality of blocks, each block corresponding to a recording spot on the printing surface.

It is also an object of the invention to provide a process as described above, and which comprises, in an advantageous embodiment, a step of recording the image on the printing surface of the recording medium.

According to a particular embodiment of the invention, the series of digital data to be coded represents the digital data of still or moving images, and/or text, and/or sound.

According to a particular embodiment of the invention, all the carrier frequencies fₓ and f_{y} are mutually orthogonal, and the step e) of image generation of the recording process of the series of digital data described above is performed by an inverse discrete Fourier transform.

It is also an object of the invention to provide a medium comprising a printing surface to record a series of digital data in coded form, in which at least one image, for example with rectangular shape, is printed on the printing surface, said image being representative of the series of digital data coded by performing the invention process described above.

According to one advantageous embodiment of the invention, the recording medium is characterized in that the printing surface is a surface sensitive to exposure to light, like for example a strip of photographic film or paper, a strip on which are recorded the digital data coded according to the invention process described above.

Other characteristics and advantages of the invention will appear in the following detailed description, with reference to the drawings of the various figures.

### BRIEF DESCRIPTION OF THE DRAWINGS

FIG. 1 represents schematically a recording system used to implement the invention.

FIG. 2 represents schematically a series of symbols used to code a series of digital data, as well as a division of a recording surface to record the series of digital data coded according to the invention process.

FIG. 3 represents schematically a diagram of the response and noise of the transmission channel of a recording system used to implement the invention process.

FIG. 4 schematically represents one example of an embodiment of the invention process.

FIG. 5 represents schematically a diagram of coding digital data according to the embodiment of FIG. 4.

FIG. 6 represents an example of a sum of two carrier frequencies in the form of an image.

### DETAILED DESCRIPTION OF THE INVENTION

The following description describes the main embodiments of the invention, with reference to the appended drawings, in which the same numerical references identify the same elements in each of the different figures.

It is the object of the invention to provide a recording process of digital data, to solve the problems set by the increase of the density of information recorded on a two-dimensional recording medium and thus approach the theoretical limit defined by the Shannon theorem.

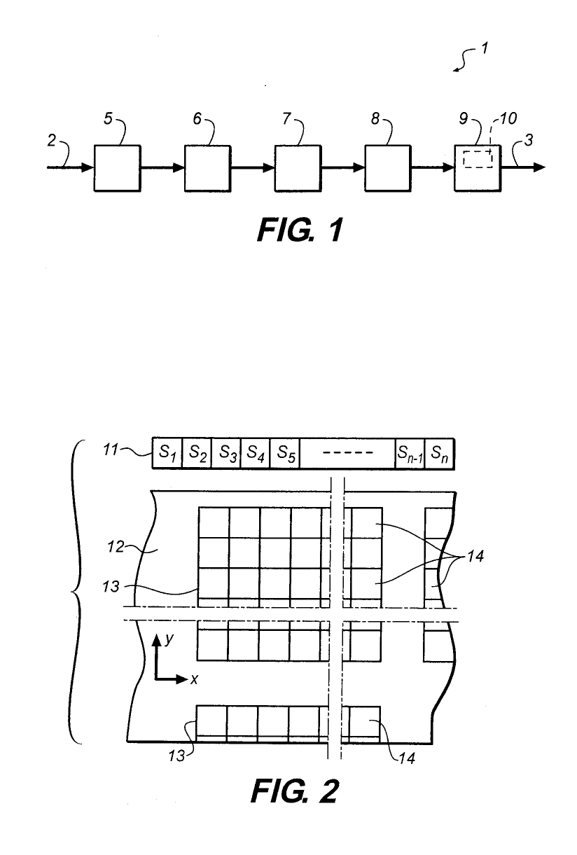

The invention can be implemented with a recording system like that shown schematically in FIG. 1. The recording system 1 comprises a coding unit 5 that can communicate symbols (values) to a recording unit or recorder 6. The coding unit 5 codes the series of digital data 2 entering the recording system with symbols (values). Additional digital data (redundant with the digital data to be coded), aiming to correct errors introduced by the transmission channel of the recording system, can be introduced at this stage. The recording system 1 also comprises a recording medium 7, a reading unit or reader 8 and a decoding unit 9. The decoding unit 9 comprises an error correction module 10. The recording unit 6 transmits, via the transmission channel of the system 1, signal values (physical quantities representing the symbols) that are recorded on elementary regions of the recording medium 7. The information recorded on the recording medium 7 (physical quantities) can be reread by the reading unit 8 then decoded by the decoding unit 9, to restore output digital data 3. If the system introduces no error, the output digital data 3 are identical to the input digital data 2. The technical function of the error correction module 10 is to correct the errors introduced by the transmission channel, so that the output digital data 3 are identical to the input digital data 2.

According to one advantageous embodiment of the invention, the recording medium 7 comprises a light sensitive surface, like for example a strip of photographic film or paper, on which are recorded the digital data coded with the invention process.

According to FIG. 2, and in the existing systems as described for example in U.S. Pat. No. 5,369,261, each symbol S₁, S₂, S₃, S₄, S₅, Sₙ₋₁, Sₙ of a series of symbols 11 is linked in a bijective way to a corresponding elementary region or block 14 of a printing or recording surface 12. The elementary region 14, called block, is characterized, for example, by its position (xᵢ, yᵢ) in the x, y axes of a coordinate system. The coordinate system is arranged, for example, in the two main axes of the recording surface 12.

But the division into blocks 14 of the recording surface 12, as shown in FIG. 2, can also be used to implement the invention process. All the elementary regions 14 are arranged so as to produce blocks of the recording surface, for example, according to a plurality of images 13 having advantageously a shape of rectangular blocks or rectangles 13. The rectangle 13 comprises all the elementary regions or blocks 14, each block 14 being also preferably of rectangular shape.

According to the Shannon theorem, the capacity of information transmission depends on the signal-to-noise ratio (S/N), i.e. on the ratio between the spread of useful intensity of the physical quantity and the standard deviation (root mean square of the variance) of interfering intensity variations.

The Shannon theorem also enables the relationship to be known between the symbol density, the number of information bits per symbol and the probability of transmission error. To best approach the theoretical maximum capacity of information transmission, it is worthwhile to adjust the number of bits per symbols and the level of resistance to errors according to the signal-to-noise report (S/N) of the whole recording system (recorder, medium and reader), as shown in FIG. 1.

Most recording systems actually have a signal-to-noise ratio that is variable according to the frequency of the signal that characterizes the physical quantity representing information. Thus their optimal use requires an adaptation of the coding according to said frequency.

The invention process, to reach the goal sought as regards state-of-the-art process, i.e. best approach the theoretical maximum capacity of information transmission, implements a large number of two-dimensional carrier frequencies and a representation in amplitude and phase of the symbols.

The amplitude A and phase φ modulation of a two-dimensional carrier frequency (fₓ, f_{y}) enables the intensity of a signal at any point (x,y) of a plane to be defined according to the following formula:
I(x,y)=A.sin (2.π.fₓ.x+2.π.f_{y}.y+φ)

This signal can be represented as an image.

If several carrier frequencies are used simultaneously, the signal is equal, at any point of the plane, to the sum of the signals of each of the carrier frequencies.

According to the example shown in FIG. 6, the image 4 represents a signal resulting from the sum of the two images 4A and 4B. The images 4A and 4B correspond respectively to a representation of the two separate carrier frequencies used simultaneously.

According to a particular embodiment, the carrier frequencies are selected to be mutually orthogonal on one region of the plane. In this case, the signal can be calculated at any point of the region by an Inverse Fourier Transform performed on the modulated carrier frequencies.

In practice, the region of the plane used is sampled in the two dimensions and the discrete version of the Fourier Transform is used.

In the rest of the description, these abbreviations will be used: DFT for Discrete Fourier Transform and IDFT for Inverse Discrete Fourier Transform. The Inverse Discrete Fourier Transform IDFT is the inverse function of the Discrete Fourier Transform DFT.

The DFT of a set of N numbers gives variations of these numbers to according to frequencies whose lower and upper limits respectively are minus one half (−½) and plus one half (+½). The DFT of a set of N numbers (N being an integer that can vary from one to infinity) gives the variations of these numbers according to the frequencies which can be expressed in the generic form of an arithmetical series at (1/N) such that:
(−½), −(N/2−1)/N, . . . , (−2/N), (−1/N), 0, (1/N), (2/N), . . . , (N/2−1)/N, (½)

The DFT and IDFT operate on complex numbers. A complex number is formed by a pair of a real part and an imaginary part.

A complex number z is represented graphically in a two :,o dimensional coordinate system according to two axes (x, y), versus a real number represented in a single dimension, for example with an x axis, that is linearly with a point placed on this single axis. The complex number z is written according to the equation:
z=a 30 ib=ρ (cosinus θ+i sinus θ)=ρe^{iθ},

equation where ρ characterizes the z modulus and θ characterizes the z argument. The complex conjugate number of z is written: Z̅=a−ib.

The sum (z+ Z̅) is a real number, as the imaginary part of (z+ Z̅) is zero.

The DFT of a set of N complex numbers is a set of N complex numbers. The modulus p and argument θ are respectively the amplitude and phase of each of the frequencies of variation of these N complex numbers. The application of the IDFT to these N complex numbers, enables the initial N complex numbers to be found.

The DFT of a set of N real numbers, i.e. of N complex numbers having a zero imaginary part, is also a set of N complex numbers. But, one half of these complex numbers is the conjugate complex of the other half. Thus, the DFT of a series of N real numbers is a set of N over two (N/2) separate complex numbers.

These properties of the DFT and the IDFT are kept for an extension, no longer to a simple series of N complex numbers, but to a two-dimensional table, of N by M (N.M) complex numbers.

Thus, the DFT of a two-dimensional table of N.M complex numbers, gives N.M complex numbers that can be understood as the frequencies of variation of these numbers according to each of the x, y axes of the recording surface 12, as shown for example in FIG. 2.

According to FIG. 2, the invention process links each symbol S₁, S₂, S₃, . . . , Sₙ₋₁, Sₙ of the series of symbols 11 to an element of the two-dimensional DFT of a rectangular block 13 of the recording surface.

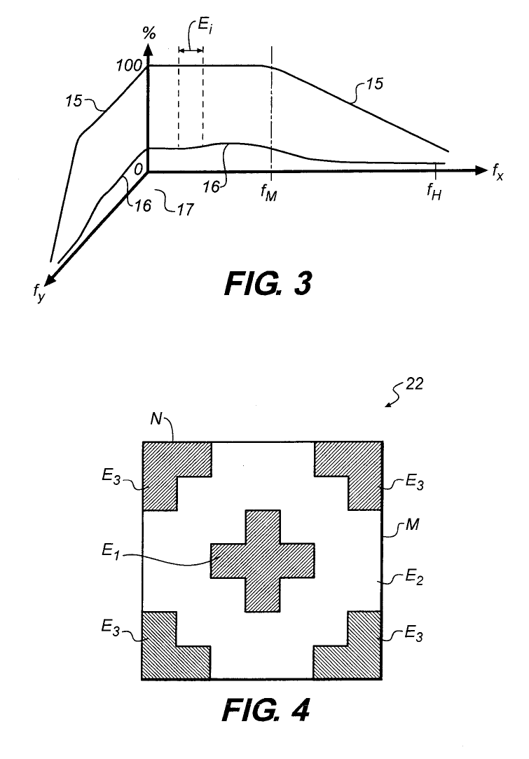

According to FIG. 3, this element of the two-dimensional DFT is characterized by its frequency (fₓ, f_{y}) according to the x, y axes of the recording surface. FIG. 3 shows an example of curves giving the response 15 and noise 16 of the transmission channel of the two-dimensional recording system 1, according to the two dimensions of said system. The bandwidth corresponds, according to the fₓ axis, to the frequency interval [0, f_{M}]. For frequencies between zero and f_{M}, the transmission channel of the recording system 1 lets the signal pass without great distortion. The “high” limit of the band of two-dimensional spatial frequencies 17, according to the fₓ axis, is for example f_{H}.

One advantage of the invention process is to divide the band of frequencies 17 by selecting the high limit f_{H} well above f_{M}. The high limit f_{H} of the band of spatial frequencies 17 in each of the two dimensions supplies the dimensions of the elementary region or block 14 (FIG. 2).

The symbols 11 are shown by different values of the pair (real part, imaginary part) that defines the value of the elements of the two-dimensional DFT, i.e. for example: (1, 1), (1, −1), (−1, 1), . . . , (3, 4), (3, −2).

A priori knowledge of the signal-to-noise ratio of the complete system 1 (FIG. 1), according to the frequency, enables the appropriate coding to be selected for each frequency, i.e. the number of bits per symbol and the level of decoding error correction.

According to FIG. 3, for frequencies (fₓ, f_{y}) low in the two directions x, y, the frequency response 15 of the whole system 1 enables a good signal-to-noise ratio, for example S/N=40 dB (decibels) to be obtained, and in the decoding, for example, sixty four (64=2⁶) different amplitude and phase combinations to be identified with a low probability of decoding error. In this case, an error correction algorithm which has low redundancy is selected, for example 6/5 (FIG. 1: addition of one error correction bit for 5 information bits) and the coding is performed with five information bits per frequency (DFT element).

At the other end of the band of two-dimensional spatial frequencies 17, a lower signal-to-noise ratio, for example S/N=10 dB can only enable four (4=2²) different amplitude and phase combinations to be identified in the decoding, and, with a higher probability of decoding error. In this case, an error correction algorithm which introduces greater redundancy is selected, for example 2/1 (FIG. 1: addition of one error correction bit for 1 information bit), and the coding is performed with only one information bit per frequency.

According to a preferred embodiment of the invention, the recording medium 7 comprises a photographic film. The elementary regions 14 of photographic film are commonly called “pixels”. The physical quantity or signal is advantageously the optical density obtained after processing of the photographic film.

FIG. 4 shows an example of a number of elements to be treated by the two-dimensional IDFT selected equal to N multiplied by M (N.M). The surface of the recording support, advantageously a photographic film, is thus divided into blocks comprising N.M pixels.

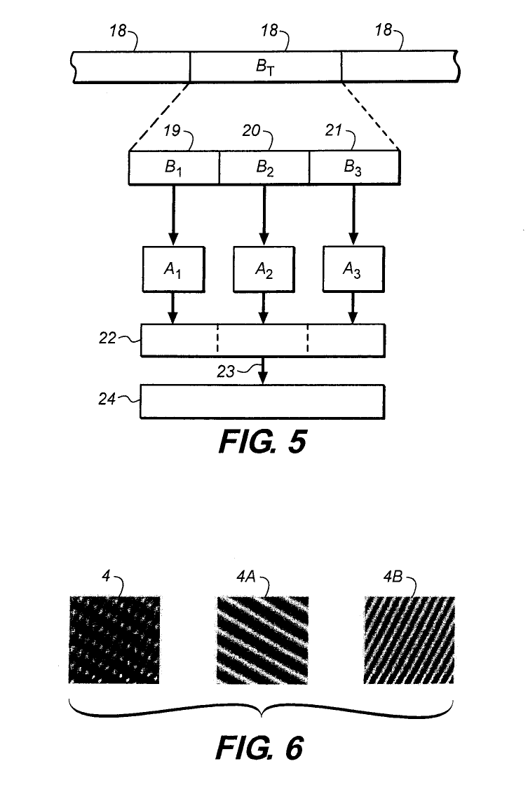

According to FIG. 5, the result of the IDFT 23 comprises real numbers 24, for example R1, R2, R3, . . . , Rn-1, Rn, given that, as described above, the number of independent transformed elements (complex numbers) is equal half of N.M, i.e. N.M/2.

An analysis of the technical characteristics of the recording system, especially its signal-to-noise ratio according to the frequency, enables the possible number of information bits for each independent element to be determined, as described above. It is possible that certain frequencies do not enable information to be coded with a acceptable probability of error: this does not question the validity of the invention process. The energy of the signal thus saved by not using these frequencies is taken advantage of to improve the signal-to-noise ratio of the used frequencies.

In an advantageous embodiment, aimed at reducing the complexity of implementing the invention process, the error correction algorithm and the representation of the symbols, named coding algorithm Aᵢ below, is selected to be identical for a subset of frequencies.

FIG. 5 shows an example with three referenced subsets 19, 20, 21 respectively, for which coding algorithms A₁, A₂, A₃ are applied respectively.

According to FIG. 5, each subset 19, 20, 21 includes N₁, N₂, N₃ elements respectively, representing B₁, B₂, B₃ bits respectively. The sum N₁+N₂+N₃ is equal to the number of independent elements (complex numbers), i.e. equal to N.M/2.

More widely, the invention process applies to any integer “i” of subsets Dᵢ, for which “i” coding algorithms Aᵢ are applied respectively. Thus, each coding algorithm Aᵢ enables Bᵢ bits to be coded on the Nᵢ elements of the subset Dᵢ.

According to the invention process, all the information bits that characterize the series of digital data 11 to be coded is divided into additional blocks 18. Each block 18 comprises B_{T} information bits and the total number of information bits that can be coded on each block 18 is equal to B_{T}, with B_{T}=B₁+B₂+B₃.

The recording process according to the invention applied to the particular embodiment of FIG. 5 comprises the following detailed steps:

a) determination of the response 15 and noise 16 of the transmission channel of the two-dimensional recording system 1, according to the frequency (fₓ, f_{y}) in the two dimensions of said recording system;

b) division of the band of spatial frequencies 17 into three subsets E₁, E₂, E₃ in which the signal-to-noise ratio (S/N) is more or less constant, preferably varying by less than 10 dB; each subset E₁, E₂, E₃ respectively contains a number N₁, N₂, N₃ of frequency samples;

c) determination, for each frequencies subset of E₁, E₂, E₃ respectively of a coding algorithm A₁, A₂, A₃ appropriate to the signal-to-noise ratio (S/N) of each subset;

d) division of the recording or printing surface 12 of the recording medium 7 into a plurality of images, each image 13 having rectangular shape and size sufficient to contain a number of elementary regions or blocks 14 greater than eight according to each of the two axes (x,y) of the recording medium 7;

e) calculation of the respective capacities in bits B₁, B₂, B₃ of each of the subsets E₁, E₂, E₃ defined in step b) respectively according to the number N₁, N₂, N₃ of frequency samples it contains, the size of the set of symbols and the level of redundancy of the coding algorithms A₁, A₂, A₃;

f) calculation of the capacity B_{T} in bits of each rectangular-shaped block 13 as defined in step d), the capacity B_{T} being the sum B₁+B₂+B₃ of the respective capacities B₁, B₂, B₃ of each subset E₁, E₂, E₃;

g) divide all the information bits of the series of digital data 11 intended to be recorded on the recording medium 7; the division is performed in blocks 18 each comprising a number B_{T} of information bits;

h) for each block 18, divide the B_{T} bits into three subsets 19, 20, 21, each subset respectively comprising a number B₁, B₂, B₃ of bits;

i) for each subset 19, 20, 21, apply the corresponding coding algorithm A₁, A₂, A₃ to the bits B₁, B₂, B₃, in order to generate respectively N₁, N₂, N₃ symbols represented by the values (amplitude and phase) of the subset frequencies E₁, E₂, E₃; concatenate (i.e. arrange) the frequencies subsets E₁, E₂, E₃ into a first table of complex numbers 22 with dimension N by M (N.M);

j) perform an IDFT 23 on these complex numbers, to produce a second table 24 of N.M real values.

In the particular embodiment with a photographic film as printing or recording surface, these N.M real values represent the value of the optical density for each pixel to be recorded.

In an advantageous embodiment of the invention process, the choice of powers of two, for the values N and M, enables an optimized version by the DFT calculation algorithm to be used, i.e. a version requiring fewer calculation operations.

Another advantage of the invention process is to dilute the effect of localized interference of the recording surface, e.g. dust, on all the symbols of a block. Indeed, one of the properties of the DFT and its inverse (IDFT) is to make the value of each element depend on the result of all the source elements. This enables the localized interference to be drowned in the natural noise of the recording system.

This advantage is conserved in the particular embodiment where there is only one subset Eᵢ comprising all the DFT elements, and thus a single coding algorithm Aᵢ.

The invention can apply to any surface capable of recording a physical quantity of variable intensity, like for example an optical density, a coefficient of reflection of light, or even a magnetic intensity.

The invention can also apply if the physical quantity only takes two different intermittent values on the recording medium. This simply means choosing a sufficiently big size of elementary region and varying the fraction of the elementary region having one of the two intermittent values. The average of the physical quantity on the elementary region can thus take various values between the two intermittent values. This process is often used in printshops, e.g. for photographs.

It is clear that the series of data to be recorded can previously have been coded or reorganized according to an appropriate algorithm.

The invention has been described in detail with particular reference to certain preferred embodiments thereof, but it will be understood that variations and modifications can be effected within the scope of the invention.

1. A process of recording a series of digital data by means of a recording system having a band of two-dimensional spatial frequencies, comprising the following steps:
a) selection in the band of spatial frequencies of disjoint subsets of carrier frequencies;
b) linking with each subset of a coding algorithm function of a signal to noise ratio (S/N) of the system in the subset of carrier frequencies, so as to give to the subset a transmission capacity function of the coding algorithm and the number of carrier frequencies of the subset;
c) distribution of the data to be recorded in the subsets according to their transmission capacity;
d) coding of the data of every subset according to the coding algorithm linked to the subset by amplitude and phase modulation of the carrier frequencies;
e) generation of an image representing the sum of the modulated carrier frequencies; and
f) recording of the image with the recording system.

2. The process of recording according to claim 1, characterized in that an addition of error correction codes is performed in the coding algorithm.

3. The process of recording according to claim 1, characterized in that the image comprises a plurality of blocks each block corresponding to a recording spot on the printing surface.

4. The process of recording according to claim 3, characterized in that the image has a rectangular shape.

5. The process of recording according to claim 1, characterized in that all the carrier frequencies and are mutually orthogonal.

6. The process of recording according to claim 1, characterized in that step e) is performed by an inverse discrete Fourier transform.

7. The process of recording according to claim 1, characterized in that the image recording is performed on the printing surface.

8. The process according to claim 1, characterized in that the series of coded digital data represents the digital data of still or moving images, and/or text, and/or sound.

9. A medium comprising a printing surface for recording a series of digital data in coded form, in which at least one image is printed on the printing surface, said image being representative of the series of digital data coded by performing the process according to claim 1.

10. The medium according to claim 9, characterized in that the image has a rectangular shape and comprises a plurality of blocks, each block corresponding to a recording spot on the printing surface.

11. The medium according to claim 10, characterized in that the block has a rectangular shape.

12. The medium according to claim 10, characterized in that the printing surface is a surface sensitive to exposure to light, like for example a strip of photographic film or paper.

13. The medium according to claim 12, characterized in that the blocks of the sensitive surface, representative of the series of coded digital data, are each exposed according to an optical density value of the sensitive surface.

14. A recording system (1) comprising a coding unit a recording unit, a recording medium, a reading unit and a decoding unit, all these units being capable of intercommunicating digital data, to implement the process according to claim 1.

15. The recording system according to claim 14, characterized in that the recording medium comprises a printing surface.
